(19) United States
(12) Patent Application Publication
(10) Pub. No.: US 2024/0334845 A1
(43) Pub. Date: Oct. 3, 2024

(54) ADDRESSABLE QUANTUM DOT ARRAY

(71) Applicant: TECHNISCHE UNIVERSITEIT DELFT, Delft (NL)

(72) Inventors: Menno Veldhorst, Zoetermeer (NL); Nico Willem Hendrickx, Delft (NL)

(21) Appl. No.: 18/574,529

(22) PCT Filed: Jun. 29, 2022
(86) PCT No.: PCT/NL2022/050372

§ 371 Date: Dec. 27, 2023

(30) Foreign Application Priority Data
Jun. 29, 2021 (NL) 2028581

(51) Int. Cl. H10N 60/10

(52) U.S. Cl. CPC H10N 60/128; H10N 60/11

(57) ABSTRACT

A quantum dot structure is described wherein the quantum dot structure comprises one or more semiconductor layers arranged on a substrate; an array comprising a plurality of quantum dot regions (104), the plurality of quantum dot regions being formed in the one or more semiconductor layers, the quantum dot regions being separated by barrier regions (106, 108), wherein first barrier electrodes (110) are arranged in one direction over the quantum dot regions (104) and second barrier electrodes (112) are arranged in a second direction over the quantum dot regions (104), in such a way that in operation quantum dots are defined in the quantum dot regions (104) by the potential barriers induced by the first and second barrier electrodes (110, 112); the first barrier electrodes (110) and second barrier electrodes (112) crossing each other at the barrier regions (108), so that each barrier region (108) is coupled to one of the first barrier electrodes (110) and to one of the second barrier electrodes (112).

### CROSS-REFERENCE TO RELATED APPLICATION(S)

This Application is a Section 371 National Stage Application of International Application No. PCT/NL2022/050372, filed Jun. 29, 2022 and published as WO 2023/277686 A1 on Jan. 5, 2023, in English, and further claims priority to Netherlands application Ser. No. 2028581, filed Jun. 29, 2021, the contents of which are hereby incorporated by reference in their entirety.

### TECHNICAL FIELD

The invention relates to addressable two-dimensional (2D) quantum dot arrays, and, in particular, though not exclusively, arrays of quantum dots comprising a coupling structure configured to locally coupling quantum dots in the array of quantum dots.

### BACKGROUND

Increasing the number of qubits of a qubit processer will present technological challenges including interconnects, imperfect device yield, qubit calibration and qubit readout. Quantum dot qubits constitute a promising platform, however a key challenge in scaling quantum dot qubits is to overcome a so-called interconnect bottleneck. Quantum dot devices have been limited to small and linear arrays and scaling to larger systems has not been resolved. Current approaches to scale quantum dot systems encompass sparse arrays, which will limit functionality and operation, or brute-force methods such as stacking many different control layers, which will severely limit the size of the two-dimensional array. For example, U.S. Pat. No. 10,692,924 and the article Silicon CMOS architecture fora spin-based quantum computer, Nature Communications, 8: 1766, by Veldhorst et al. described operation of a 2D array of qubits operated by a CMOS circuit layer that is provided over the 20 qubit array. These designs are based on local transistor-controlled charge detection but require extensive downscaling and new design of the CMOS circuitry.

A further scheme is based on shared control, wherein multiple plunger and/or barrier gates are controlled via a single shared line. For example, Li et al., propose in their article a crossbar network for silicon quantum dot qubits, Sci. Adv. 2018, a large scale 2D qubit array based on a crossbar design for controlling a large number of qubits. The design, which includes gate lines that are shared by multiple qubits, provides a relatively simple and scalable wiring structure for a qubit processor. The design however requires uniform fabrication parameters to ensure limited variability in threshold voltage, charging energy and tunnel coupling between different sites. Such accurate control of the variability between qubits still poses significant challenges. Moreover, the shared line does not provide local control in the two-dimensional array of quantum dots. The requirements on the uniformity are well beyond any practical demonstration in the literature, thus questioning its feasibility.

Hence, from the above it follows that there is a need in the art for improved addressable quantum dot arrays. In particular, there is a need in the art for a scalable architecture for large area quantum dot arrays that allow local control of quantum dots in the array of quantum dots which can be operated as qubits.

### SUMMARY

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Functions described in this disclosure may be implemented as an algorithm executed by a microprocessor of a computer. Furthermore, aspects of the present invention may take the form of a computer program product embodied in one or more computer readable medium(s) having computer readable program code embodied, e.g., stored, thereon.

The embodiments in this application relate to schemes and structures for addressing qubits that are arranged in a grid. In particular, schemes and structures are described that provide addressability to couple qubits. This way

It is an objective of the embodiments in this disclosure to reduce or eliminate at least one of the drawbacks known in the prior art.

In a first aspect, the embodiments may relate to a quantum dot structure comprising: one or more semiconductor layers arranged on a substrate: an array of quantum dot regions, the plurality of quantum dot regions being formed in the one or more semiconductor layers, the quantum dot regions being separated by barrier regions; first barrier electrodes arranged in one direction over the quantum dot regions and a second barrier electrodes arranged in a second direction over the quantum dot regions; and, the first barrier electrodes and second barrier electrodes crossing each other at the barrier regions. This way each barrier region is coupled to one of the first barrier electrodes and one of the second barrier electrodes. Typically, the coupling is an electrostatic coupling, e.g. a capacitive coupling.

In an embodiment, one or more first barrier electrodes and one or more second barrier electrodes may form a multi barrier electrode structure arranged over a barrier region. Thus, an addressable barrier electrode structure for a quantum dot structure, preferably a large area two-dimensional quantum dot array, is provided that allows local adjustment of coupling between two adjacent (neighboring) quantum dots. The quantum dots may be configured as qubits. Barrier electrodes that cross each other in a predetermined barrier region between two quantum dot qubits can selected and operated to achieve local interaction, e.g. entanglement, of two quantum dot qubits. This way, a double barrier electrode structure comprising two barrier electrodes between two neighboring quantum dots may be formed. Two barrier electrodes allow local control of coupling of two qubits. However, the switching may affect a qubit state. To correct this, additional barrier electrodes may be used. Thus, in further embodiments, a multi-barrier electrode structure including a plurality of barrier electrodes (i.e. more than two barrier electrodes) between two neighboring quantum dots may be realized.

In operation, a voltage may be applied to a pair of barrier electrodes that cross each other above a barrier area between two quantum dots. Voltages may be selected such that a voltage applied to only one of the electrodes in the barrier areas still provides a sufficient potential barrier for decoupling the quantum dots. In contrast, applying a voltage to both barrier electrodes may lower the coupling barrier and allow coupling between the two quantum dots that are separated by this vertical barrier region.

In an embodiment, the first barrier electrodes may be arranged over the substrate in a first diagonal direction and the second barrier electrodes in a second diagonal direction.

In an embodiment, the first and second barrier electrodes are arranged over the barrier regions. In an embodiment, the gate electrodes are arranged over the substrate, each gate electrode comprising a plurality of plunger gates arranged over a plurality of quantum dot regions. In these embodiments, the barrier regions are arranged in the peripheral parts of the quantum dot region, i.e. the regions that form the barrier regions between the quantum dot regions. When arranged diagonally over the substrate, the barrier electrodes form staircase-shaped electrodes arranged over the substrate in two different directions. This way, central parts of the quantum dots regions are not covered by the electrodes leaving space for other electrodes, such as gate electrodes, that are used to control the potential of the quantum dot region and/or to form a quantum well in the quantum dot regions.

In an embodiment, one or more insulating layers may electrically insulate the first and second barrier electrodes from the one or more semiconducting layers.

In an embodiment, one or more single electron tunneling (SET) transistors may be formed in the one or more semiconductor layers, each of the one or more SET transistors may comprise a source and a drain connected by tunneling junctions to a conductive island.

In this embodiment, one or more SET transistor may be formed in (within) the array of quantum dots, wherein the source, drain and gate electrodes of the SET transistor are formed in a different layer than the source and drain regions and the gate of the SET transistor. This way, SET transistor readout structures can be realized wherein the quantum dot regions are formed around the SET transistor so that a large number of quantum dot regions can be read out.

Barriers regions between the quantum dot regions may be locally controlled using at least two barrier electrodes. Quantum dots may be configured as qubits and by locally controlling a barrier region between two qubits based on the two barrier electrodes the coupling between the qubits can be controlled. The state of the quantum dots before and after interaction can be measured using the SET transistor as a highly sensitive charge sensor which may be capacitively coupled to the quantum dots.

Nano-scale metallic vias may galvanically connect the source and drain of the SET transistor with the source and drain electrodes. The SET readout structure is easily scalable by integrating a plurality of such SET readout structures regularly distributed over a large area quantum dot structure.

It is well known that single charge carrier devices such as a SET transistor can be implemented in materials that have mobile electrons or mobile holes. Hence, in this application the term SET transistor should be construed as encompassing both single-electron tunnelling (SET) transistors and single hole tunnelling (SHT) transistors.

In an embodiment, the quantum dot structure according may further comprise a source electrode and a drain electrode arranged over the one or more insulating layers; a first and second nano-scale metallic via through the one or more insulating layers for connecting the source and drain of one of the one or more SET transistors to the source and drain electrodes respectively; and, optionally, a third nano-scale metallic via through the one or more insulating layers for connecting a plunger electrode that is capacitively connected to the conductive island to a gate electrode arranged over the one or more insulating layers.

In an embodiment, the cross-sectional dimensions of the nano-scale metallic vias may be selected between 500 and 10 nm, preferably between 400 and 20 nm, more preferably between 200 and 20 nm.

In an embodiment, one end of the first metallic via and one end of the second metallic via form ohmic contacts, preferably a nano-scale ohmic contacts, more preferably a metal germanium-based ohmic contact, with the one or more semiconductor layers.

In an embodiment, the dimensions of the quantum dot regions may be selected between 200 and 20 nm, preferably 100 and 40 nm.

In an embodiment, at least part of the barrier electrodes, the gate electrodes and/or the metallic vias may be made of metal that becomes superconductive below a critical temperatures. In an embodiment, metals for the metal vias include Al, Nb, NbN, TiN, NbTiN. These metals will become superconducting below a certain critical temperature. Thus providing very low loss electrodes. In a further embodiment, platinum may be used as a metal for the vertical vias thereby forming Pt—SiGe or Pt—Ge contacts. An annealing step may be used to form an alloy at the interface of this contacts in to form a platinum silicide compound such as platinum silicide PtSi or platinum germanosilicide PtSiGe or a platinum germanide compound such as platinum germanide PtGe; These platinum silicide and germanide alloys will become superconducting below a critical temperature thus providing very low loss superconducting ohmic contacts with the quantum well.

In an embodiment the one or more semiconductor layers include a semiconductor heterostructure, a MOS structure, a semiconductor-on-insulator structure such as silicon-on insulator SOI, or geometries such as finFET, nanowires, hut wire, and self-assembled structures.

Particular suitable silicon based semiconductor quantum dot platforms include silicon-compatible quantum dot structures including silicon-germanium heterostructures and silicon metal-oxide-semiconductor (SIMOS) structures. Examples of such structures are describe in the article by Lawrie et al, Quantum Dot Arrays in Silicon and Germanium, Appl. Phys. Lett. 116, 080501 (2020), which is hereby incorporated by reference into this application. For example, in an embodiment, the semiconductor layer stack may include a Silicon substrate, an intrinsic Silicon layer, an isotopically purified Silicon (²⁸Si) epitaxial layer and a SiO2 layer. In another embodiment, the semiconductor layer stack may include a Si/SiGe heterostructure formed on a Silicon substrate, wherein the Si/SiGe heterostructure may include a graded Si₁₋ₓGeₓ layer and an isotopically purified Silicon (²⁸Si) epitaxial layer between two SiGe layers. In another embodiment, the semiconductor layer stack may include a Ge/SiGe heterostructure formed on a Silicon substrate, wherein the Ge/SiGe heterostructure includes a Germanium layer formed on the Silicon substrate followed by a reversed graded Si₁₋ₓGeₓ and a Ge epitaxial layer between two SiGe layers.

In an embodiment, the plurality of quantum dot regions may form a 2D array of quantum dot regions or a 3D array of quantum dot regions. In an embodiment, pitch between neighboring quantum dots (the inter-dot pitch) in the array may be selected between 200 and 50 nm.

In an aspect, the embodiments may further relate to a qubit processor comprising a quantum dot structure according to any of the embodiments described in this application.

In a further aspect, the embodiments may relate to a quantum dot processor comprising: one or more semiconductor layers arranged on a substrate; a plurality of quantum dot regions, the plurality of quantum dot regions being formed in the one or more semiconductor layers; the quantum dot regions being separated by barrier regions; first barrier electrodes arranged in one direction over the quantum dot structure and second barrier electrodes arranged in a second direction over the quantum dot structure so that each one of the first barrier electrodes crossing one of the second barrier electrodes at one of the barrier regions; and, a controller configured to locally change the coupling between two neighboring quantum dots of the plurality of quantum dot based on the first and second barrier electrodes.

Thus, a quantum dot processor comprising an array of quantum dots separated by barrier regions (and a barrier electrode structure connected to control and readout electronics arranged along the sides of the quantum dot array) is provided.

The control electronics may be configured to apply signals to the barrier electrodes, wherein a signal may comprise control pulses at different time instances. Simultaneously applying a voltage signal to barrier electrodes that are configured to locally control a coupling between a pair of neighboring quantum dots in the array of quantum dots may cause a change in the coupling between the quantum dot pair.

Voltages may be selected such that a voltage applied to only one of the electrodes in the barrier areas still provides a sufficient potential barrier for decoupling the quantum dots. In contrast, applying a voltage to both barrier electrodes may lower the coupling barrier and allow coupling between the two quantum dots that are separated by this vertical barrier region.

In an embodiment, the controller may be configured to select a first barrier electrode from the first barrier electrodes and a second barrier electrode from the second barrier electrodes, the selected first and second barrier electrodes crossing each other at a barrier region between the two neighboring quantum dot; and, to simultaneously apply a first signal to the selected first barrier electrode and a second signal to the selected second barrier electrode.

The embodiments will be further illustrated with reference to the attached drawings, which schematically will show embodiments according to the invention. It will be understood that the invention is not in any way restricted to these specific embodiments.

### BRIEF DESCRIPTION OF THE DRAWINGS

FIG. 1A-1D depict schematics of a barrier electrode structure for a quantum dot array and a quantum dot array processor comprising such barrier electrode structure according to an embodiment of the invention;

FIGS. 2A and 2B depict schematics of a barrier electrode structure for a quantum dot array according to an embodiment of the invention;

FIGS. 3A and 3B depict barrier electrode structures for a quantum dot array according to various embodiments of the invention;

FIG. 4A-4C depict a top view and two cross sections of a semiconductor structure according to an embodiment of the invention.

FIG. 5A-5C depict a top view and two cross sections of the semiconductor structure according to an embodiment of the invention;

FIG. 6 depicts a schematic of a semiconductor structure according an embodiment of the invention;

FIG. 7 depicts a schematic of a quantum dot array comprising an integrated SET readout structure according to an embodiment of the invention:

FIG. 8A-8C depicts a top view and two cross sections of the semiconductor structure according to an embodiment of the invention;

FIG. 9A-9C depicts a top view and two cross sections of the semiconductor structure according to an embodiment of the invention;

FIG. 10 depicts an ohmic connection to an integrated SET transistor readout structure according to an embodiment of the invention;

FIGS. 11A and 11B depicts pictures of 2D quantum dot arrays according to various embodiments of the invention.

### DESCRIPTION OF THE EMBODIMENTS

The embodiments in this disclosure describe coupling structures for a two-dimensional qubit array. In particular, the embodiments in this disclosure aim to provide addressable barrier electrode structures for large area quantum dot arrays structures, wherein the quantum dots may be operable as qubits. The barrier electrode structures allow local coupling of quantum dots by locally applying a signal to a barrier region between a quantum dot pair in a quantum dot array.

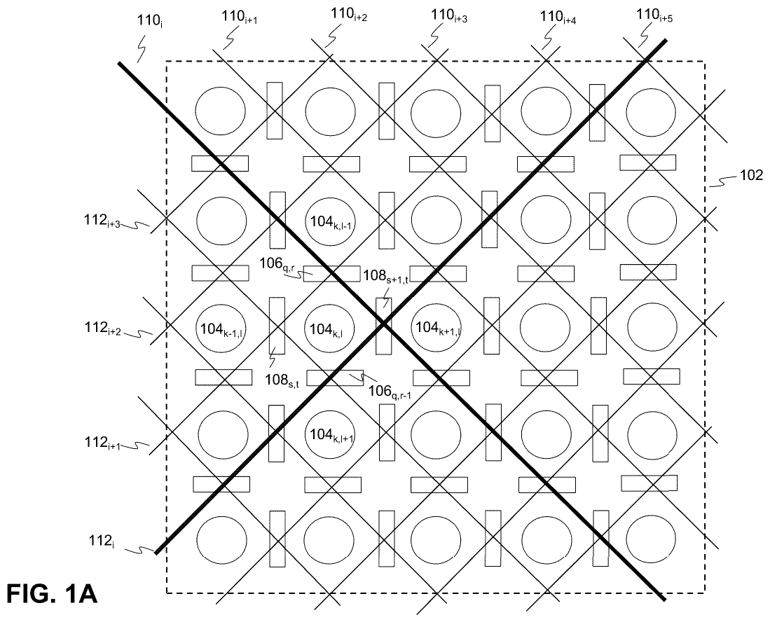

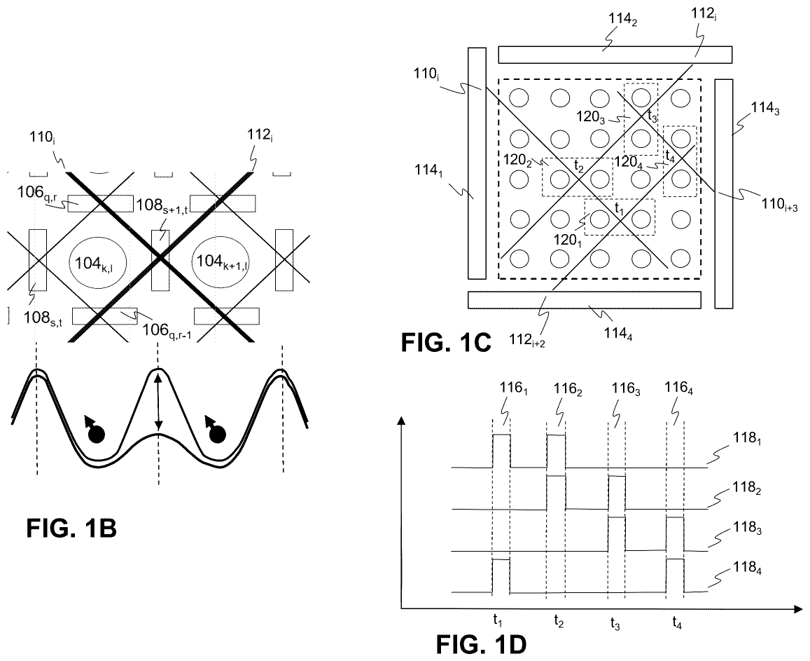

FIGS. 1A and 1B depict schematics of a quantum dot array comprising a scalable quantum dot coupling structure according to an embodiment of the invention. FIG. 1A represents a schematic top view of part of semiconductor substrate 102 comprising regions 104_{k,l} in which a quantum dot may be formed. The quantum states of a quantum dot, e.g. the spin state of a single charge carrier e.g. an electron or hole in the quantum dot, may be used to configure and operate a quantum dot as a qubit. Different types of quantum dots may be envisaged, e.g. quantum dots formed in a stack of semiconductor layers in which a two-dimensional electron gas (2DEG) or a two-dimensional hole gas (2DHG) is formed. The quantum dot regions may be arranged in an array of k rows and l columns.

The quantum dot regions may be separated by barrier regions, in particular first barrier regions located between neighboring quantum dots in a row. These first barrier regions may be referred to as row barriers. Further, second barrier regions may be located between neighboring quantum dots in a column. These second barrier regions may be referred to as column barriers. This way, a quantum dot 104_{k,l} within the 2D array may have a plurality of neighboring quantum dots 104_{k-1,l}, 104_{k+1,l}, 104_{k-l,1}, 104_{k+l,1}, in this example four quantum dots, separated by first (column) barrier regions 106_{q,r}, 106_{q,r-1} and second (row) barrier regions 108_{s,t}, 108_{s+1,t}. These barrier regions may be controlled based on barrier electrodes that are arranged over the substrate as shown in the figure.

A set of first barrier electrodes may be arranged in a first direction, in this example a first diagonal direction, over the substrate such that each first barrier electrode may be arranged over a first plurality of column and/or row barriers regions so that each first barrier electrode electrostatically couples to the first plurality of column and/or row barriers regions. For example, in the embodiment depicted in FIG. 1A, the first barrier electrodes may be alternately arranged over column and row barriers in a first direction. Similarly, a set of second barrier electrodes may be arranged in a second direction, in this example a second diagonal direction, over the substrate such that second barrier electrode may be arranged over a second plurality of column and/or barrier regions so that each second barrier electrode electrostatically couples to the second plurality of column and/or row barriers regions. For example, the second barrier electrodes may be alternately arranged over column and row barriers in a second direction. The electrodes may be arranged such that at each barrier region, at least two barrier electrodes, a first barrier electrode in a first direction, and a second barrier electrode, meet or cross each other, so that each barrier region can be effectively controlled by the two barrier electrodes. Although FIG. 1A depicts a diagonal arrangement of barrier electrodes, other angular arrangements e.g. horizontal and vertical, are also possible.

As shown in FIG. 1B, by controlling barrier electrodes 1101 and 1121, barrier region 108_{s+1,t} between neighboring quantum dots 104_{k,l}, 104_{k+1,l} may be controlled. For example, a voltage for barrier electrodes 110ₗ and 112ₗ, may be selected such that if a voltage is applied to both electrodes coupling between quantum dots 104_{k,l}, 104_{k+1,l} may be achieved. Electronic control of the barrier electrodes and the associated interaction between neighboring quantum dots is further illustrated by FIGS. 1C and 1D. FIG. 1C schematically depicts a quantum dot processor comprising an array of quantum dots separated by barrier regions (as e.g. explained in FIG. 1A) and a barrier electrode structure connected to control and readout electronics 114₁₋₄ arranged along the sides of the quantum dot array. For clarity reasons not all barrier electrodes are illustrated.

First barrier electrodes arranged in a first direction over the quantum dot array and second barrier electrodes arranged in a second direction over the quantum dot array may be connected to control electronics. Further, the control electronics may generate control signals as depicted in FIG. 1D. In particular, first control electronics 114_{1,3} may be configured to generate first control signals for the first barrier electrodes, including first barrier electrodes 110ₗ and 110ₗ₊₃. Similarly, second control electronics 114_{2,4} may be configured to generate second control signals for the second barrier electrodes, including second barrier electrodes 112ₗ and 112ₗ₊₂. An example of a first control signal 118₁ for first barrier electrode 110ₗ, a second control signal 118₂ for second barrier electrode 112ₗ, a third control signal 118₃ for first barrier electrode 110ₗ₊₃ and a fourth control signal 118₄ for second barrier electrode 112ₗ₊₂ are illustrated in FIG. 1D (the signals have an arbitrary offset for clarity).

As shown in this figure, the signals may comprise control pulses at different time instances t₁₋₄ causing coupling of quantum dot pairs 120₁₋₄. At first time instance t₁, a pulse is simultaneously applied to first electrode 110ₓ and second electrode 112ₓ. This way, a combined voltage is applied to the barrier region between the quantum dots of first quantum dot pair 120₁, causing the barrier to lower and coupling of the first quantum dot pair 120₁. Similarly, at second time instance t₂, a pulse is simultaneously applied to first electrode 110ₓ and second electrode 112ₓ, causing coupling of the second quantum dot pair 120₁, at third time instance t3, a pulse is simultaneously applied to first electrode 110ₓ and second electrode 112ₓ, causing coupling of the third quantum dot pair 120₃ and at fourth time instance t₄, a pulse is simultaneously applied to first electrode 110ₓ and second electrode 112ₓ, causing coupling of the fourth quantum dot pair 120₄.

Electronic control of the barrier electrodes allows local control of the coupling between quantum dots in the 2D array. In an embodiment, (some of the) quantum dots may be configured as qubits. In that case, control of the barrier gates allows two qubits to interact, e.g. entangle, with each other. This is illustrated in FIG. 1B. The voltage on two barrier gate electrodes 110ₗ, 112ₗ that control barrier region 108_{s+1,t} may be changed so that the states of the two quantum dots may become entangled. In another embodiment, local barrier control may be used to configured to barrier regions of a quantum dot regions as tunnel junctions. This way, a SET transistor may be realized that is integrated within the quantum dot array. Examples of such applications will be described hereunder in more detail with reference to the figures.

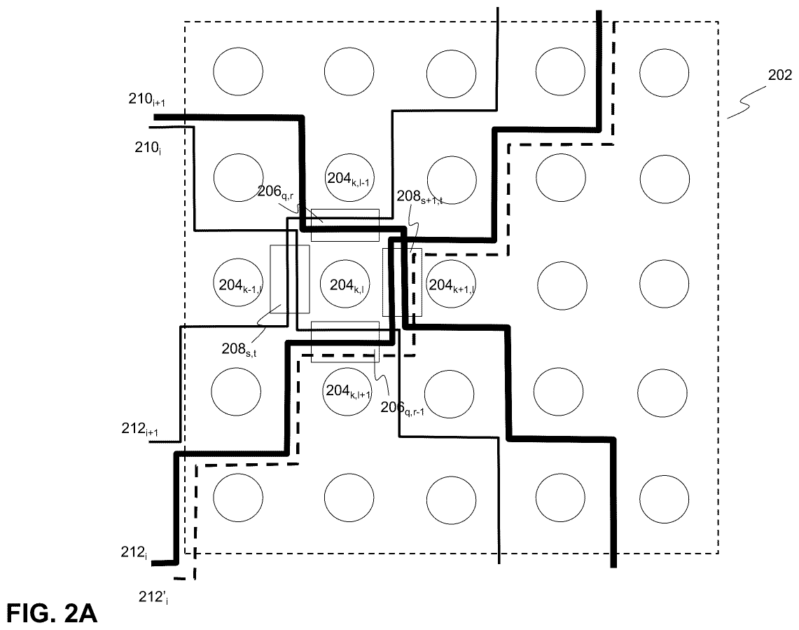

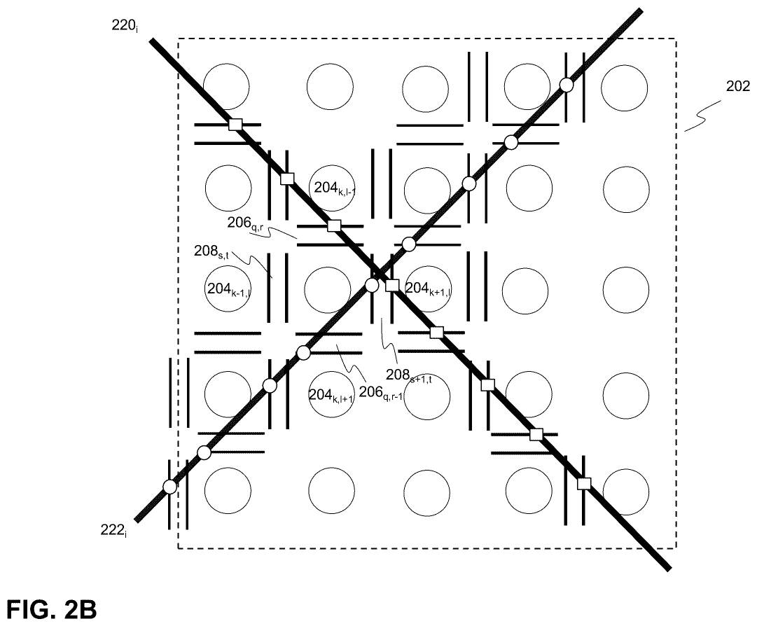

FIG. 2A depicts a quantum dot array comprising a scalable quantum dot coupling structure according to an embodiment of the invention. In particular, the figure illustrates an implementation of the barrier electrodes for providing local coupling of quantum dots in the 2D array of quantum dots. In this particular embodiment, a set of staircase-shaped first barrier electrodes 210ₗ, 210ₗ₊₁ may be arranged in a first diagonal direction over a substrate 302 and a set of staircase-shaped second barrier electrodes 212ₗ, 212ₗ₊₁ may be arranged in a second diagonal direction over the substrate (for clarity reasons only a few (in this example four) barrier electrodes are visible in the figure).

The first and second set of staircase-shaped barrier electrodes may be arranged in the peripheral part of the areas that form the quantum dots. This way, further plunger gate electrodes can be arranged in the central part of the quantum dot area. Such plunger gates may be needed to create a quantum dot in the semiconductor layers. Each staircase barrier electrode includes vertical parts and horizontal parts. In order to electrically isolate the two sets of barrier electrodes, the electrodes may be formed in different layers on the substrate including at least one dielectric layer for electrically separating both barrier electrodes.

As shown in the figure, the barrier electrodes are arranged to define quantum dots 204_{k-1,l}, 204_{k+1,l}, 204_{k,l}, 204_{k,l-1}, 204_{k,l+1} separated by first (column) barrier regions 206_{q,r}, 206_{q,r-1} and second (row) barrier regions 208_{s,t}, 208_{s+1,t}. A barrier region may be controlled by a first barrier electrode in the first diagonal direction and a second barrier electrode in the second diagonal direction. For example, vertical barrier region 208_{s+1,t}, may be controlled by a vertical part of first barrier electrode 210ₗ₊₁ and a vertical part of the second barrier electrode 212ₗ. Similarly, horizontal barrier region 206_{q,r-1} may be controlled by a horizontal part of first barrier electrode 210ₗ and a horizontal part of the second barrier electrode 212ₗ. For clarity reasons, only a few barrier electrodes 210ₗ, 210ₗ₊₁, 212ₗ, 212ₗ₊₁ are illustrated. Further barrier electrodes may be arranged over the substrate so that all barrier regions between the quantum dots can be locally controlled.

In operation, a voltage may be applied to a pair of barrier electrodes that cross each other above a barrier area between two quantum dots (similar to the situation depicted in FIG. 1). The voltages may be selected such that a voltage applied to only one of the electrodes in the barrier areas still provides a sufficient potential barrier for decoupling the quantum dots. In contrast, applying a voltage to both electrodes that control vertical barrier region 208_{s+1,t}, may lower the coupling barrier and allow coupling between the two quantum dots that are separated by this vertical barrier region.

In FIG. 2A an embodiment is shown in which an addressable double barrier electrode is formed over barrier regions. In some embodiments however, it may be advantageous to have more than two barrier electrodes to control a barrier region between two neighboring quantum dots. Two barrier electrodes allow local control of coupling of two qubits. However, the switching may affect a qubit state. To correct this, additional barrier electrodes may be used. Thus, in further embodiments, a multi-barrier electrode structure including a plurality of barrier electrodes (i.e. more than two barrier electrodes) between two neighboring quantum dots may be realized.

An example of such multi-barrier electrode structure over a barrier area is shown in FIG. 2A wherein next to barrier electrode 212ₗ a further barrier electrode 212′ₗ may be arranged resulting in a three-barrier electrode structure over barrier region 208_{s+1,t}. In that case, the voltages applied to the different barrier gates need to be selected carefully so that local coupling is only established between the addressed quantum dots (in this example e.g. 204_{k,l}, 204_{k,l-1}.

FIG. 2B depicts a quantum dot array comprising a scalable quantum dot coupling structure according to another embodiment of the invention. Also this embodiment, includes barrier electrodes for providing local coupling of quantum dots in the 2D array of quantum dots. However, in contrast to the staircase type electrodes depicted in FIG. 2A, in this particular embodiment, pairs of metal strips are arranged over the vertical and horizontal barrier regions between the quantum dot regions. The metal strip pairs are arranged in a layer and electrically isolated from each other.

Thus, metal strip pairs may be arranged horizontally and vertically to define quantum dots regions 204_{k-1,l}, 204_{k,l}, 204_{k+1,l}, 204_{k,l-1}, 204_{k,l+1} separated by first (column) barrier regions 206_{q,r}, 206_{q,r-1} and second (row) barrier regions 208_{s,t}, 208_{s+1,t}. Then, a first insulating layer may be formed over the quantum dot regions and openings may be formed in the first insulating layer at positions of the metal strip pairs to expose one of the underlying metal strips. The openings may be arranged in a first direction over the quantum dot array. Metal vias 210ₗ may be formed in the openings to form first vertical metallic vias in the first insulating layer. A first barrier electrode 222ₗ may be formed over the first metallic vias. This way, a first barrier electrode may be formed connecting horizontal and vertical metal strips in the peripheral part of (the vertical and horizontal) barrier regions between the quantum dots.

A further second insulating layer may be formed over the structure to insulate the first barrier electrode from a further second barrier electrode 220ₗ, which may be formed over the quantum dot array in a second direction. The second barrier electrode may be formed in a similar was the first barrier electrode, i.e. formation of openings arranged in a second direction over the quantum dot array in the first and second insulating layers to expose one of the underlying metal strips, formation of metallic vias in the openings and a second barrier electrode formed over the metallic vias to form the second barrier electrode.

As shown in the figure, the first and second barrier electrodes 220ₗ, 222ₗ control the voltage over the two metal strip pairs arranged over barrier region 208_{s+1,t} between quantum dots 204_{k,l}, 204_{k+1,l}. For clarity reasons, only two barrier electrodes 310ₗ, 222ₗ are illustrated. Further barrier electrodes may be arranged over the substrate so that all barrier regions between the quantum dots can be locally controlled.

Similar to FIG. 2A, also in the example of FIG. 2B it is possible to realize barrier electrode structures over a barrier regions that include mode than two barrier electrodes (e.g. three or even four) in order to achieve accurate control over the coupling between the quantum dots that may be configured as qubits.

Thus, the examples in these figures illustrate the use of barrier electrodes that allow local control of a barrier region between two quantum dots in a large quantum dot array. It is submitted that the electrode structures depicted in FIGS. 2A and 2B are non-limiting examples and many different variations exist without departing the essence of the invention. For example, barrier electrodes of FIG. 2A may be combined with barrier electrodes of FIG. 2B. Further, instead of two barrier electrodes to control a barrier region, three or more barrier electrodes may be used.

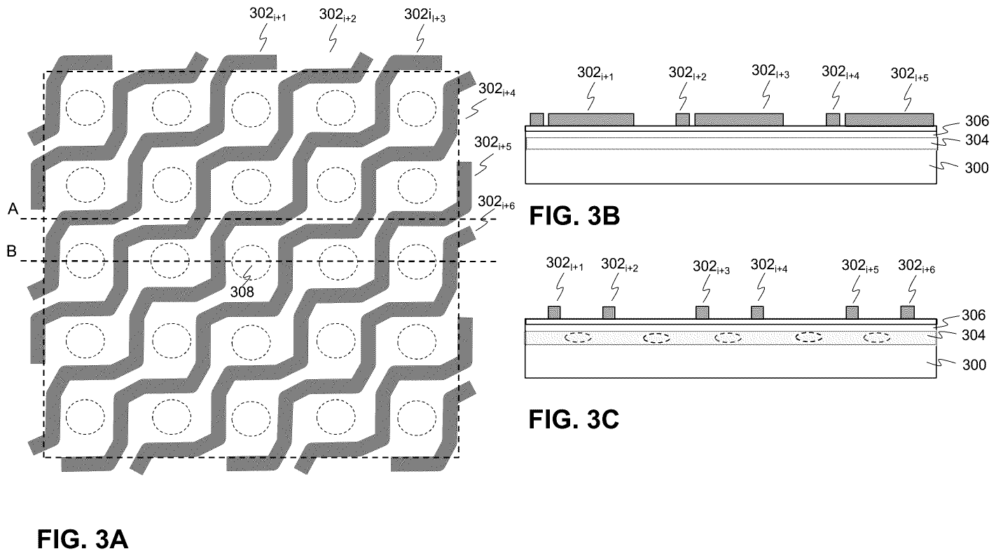

FIG. 3-9 illustrate a method for forming a quantum dot structure according to an embodiment of the invention. These integrated structures may be realized based on fabrication techniques that are known in the field of semiconductor technology, including thin-film deposition techniques and lithography techniques and dry and/or wet (selective) etching techniques based on patterned masks. In particular, FIG. 3A-3C depict a top view and two cross sections of a semiconductor structure after first fabrication steps in which a first barrier electrode structure is formed on a semiconductor structure. As shown in FIGS. 3B and 3C, the semiconductor structure includes a substrate 300 comprising one or more semiconductor layers 304 in which quantum wells may be formed. For example, a quantum well may be formed in the semiconductor layers by applying a voltage to a plunger gate that is realized over the quantum dot region 308 as defined by the electrode structure. Examples of such plunger gate structures are described hereunder in more detail.

A first insulating layer 306 may be formed over the semiconductor layers. As shown in FIG. 3A, a first patterned metallic layer comprising a plurality of first barrier electrodes 302ₗ₊₁, 302ₗ₊₂, 302ₗ₊₃, 302ₗ₊₄, 302ₗ₊₅, 302ₗ₊₆ may be formed over the insulating layer in a first direction, in particular a first diagonal direction. As shown in FIG. 3A, the first barrier electrodes have a staircase shape comprising horizontal and vertical parts arranged at the peripheral area of quantum dot regions 308.

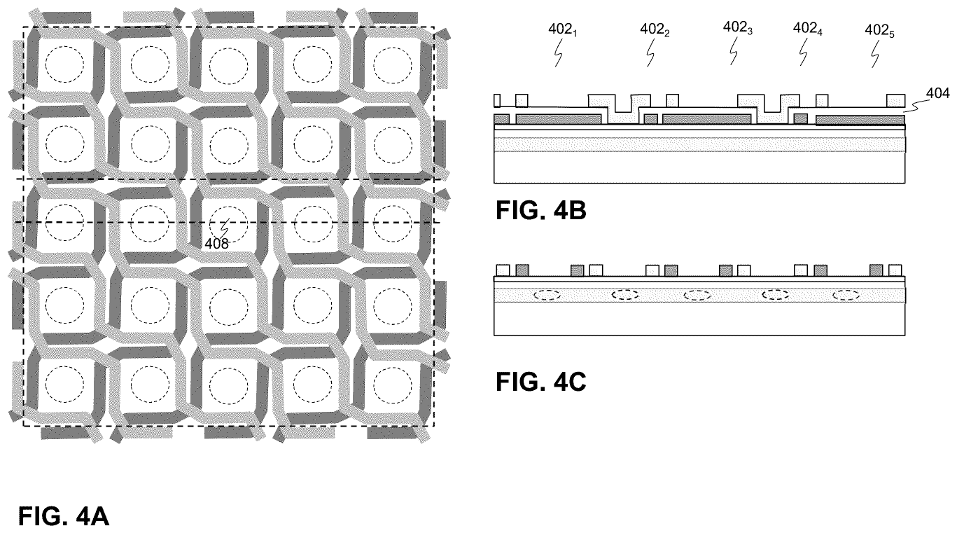

FIG. 4A-4C depict a top view and two cross sections of the semiconductor structure after second fabrication steps in which a second insulating layer 404 is formed over the first barrier electrodes. Further, a second patterned metallic layer comprising a plurality of second barrier electrodes 402ₗ₊₁, 402ₗ₊₂, 402ₗ₊₃, 402ₗ₊₄, 402ₗ₊₅, 402ₗ₊₆ is formed over the second insulating layer in a second direction, in particular a second diagonal direction. As shown in FIG. 4A, also the second barrier electrodes may have a staircase shape comprising horizontal and vertical parts arranged at the peripheral areas of quantum dot regions 408. The resulting electrode structure form a barrier electrode structure including staircase type electrodes arranged in two opposite diagonal directions, defining quantum dot regions in which quantum wells may be formed, separated by barrier regions. The double barrier gate structure provided over the barrier regions are used to locally control the coupling between neighboring quantum dots. This way, a barrier electrode structure is formed that is similar to the barrier structure described with reference to FIG. 2A allowing locally addressable coupling barriers in a two-dimensional quantum dot array.

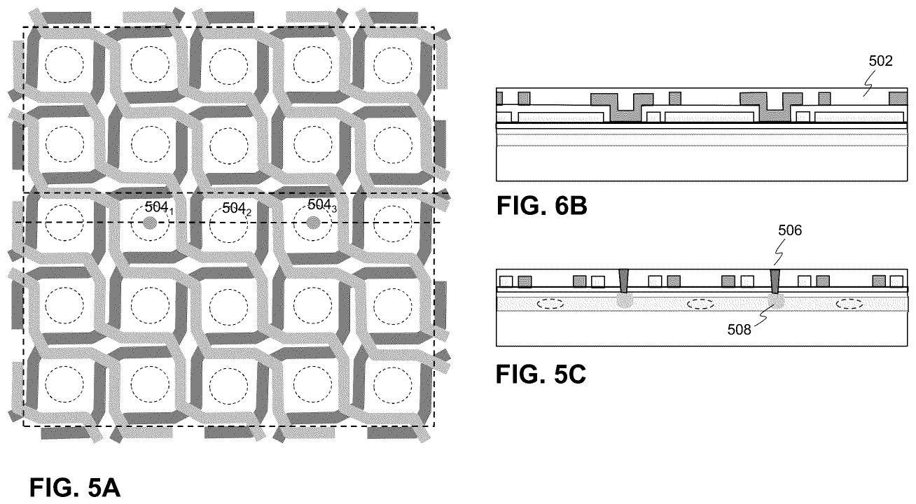

FIG. 5A-5C depict a top view and two cross sections of the semiconductor structure after third fabrication steps wherein a further third insulating layer 502 may be formed over the barrier electrode structure. Further, in this step a readout region within the quantum dot regions may be selected in which a SET transistor may be formed. The readout region may include a number of quantum dot regions 504₁,504₂,504₃, in this example three quantum dot regions which may be used in the formation of source and drain regions of the SET transistor and the island of the SET transistor. Lithography and etching steps may be used to form nano-scale openings through the first, second and third insulating layer to expose at least one semiconductor layer of the one or more semiconductor layers in which the quantum dots are formed. Nano-scale metallic vias 506 are subsequently formed in the openings to provide a galvanic connection between areas in the semiconductor layer which may form the source and drain of a SET transistor and metallic electrode structures that are formed in further fabrication steps. The nano-scale metallic via may form a metal semiconductor contact. In some embodiments, a diffusion step may be used to form a diffusion area 508 at the metal semiconductor contact to improve Ohmic behavior of the galvanic connection.

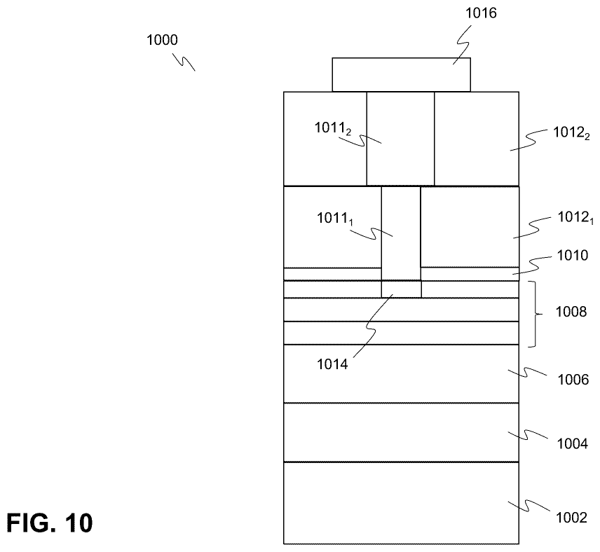

In an embodiment, a nanoscale metal contact structure may be used that is described with reference to FIG. 10. As shown in this figure, a silicon germanium SiGe quantum well structure 1008 may be provided on a silicon substrate 1002. A germanium layer and a graded silicon germanium layer may be provided between the silicon substrate and the quantum well structure. The silicon germanium quantum well may include a SiGe/Ge/SiGe strained quantum well structure. An example of such structure is described in the article by the article by Sammak et. al., Shallow and Undoped Germanium Quantum Wells: A Playground for Spin and Hybrid Quantum Technology, Advanced Functional Materials, 23 Jan. 2019, which hereby may be incorporated by reference into this application. Further, a thin silicon capping layer and an insulating layer 1012₁ may be provided over the quantum well structure. Vertical Ohmic contacts to the germanium quantum well layer may be realized by forming a hole in the insulating layer and the capping layer using e.g. anisotropic reactive ion etching to expose the SiGe layer and forming a metal via 10111 in the opening that contacts the SiG or Ge layer. An annealing step may provide some diffusion of the metal into the SiGe to form a direct metal contact with the Ge quantum well layer. Unlike silicon based platforms such as SiMOX or Si/SiGe hetetrosructures, Ge/SiGe do not require high fluence P ion implantation followed by Ti:Pt metallic contacts in order to form n++ doped low resistance metallic contact. Instead a low resistance contact can be made by contacting the Ge quantum well layer directly. This way, nano-scale vias can be realized to directly contact the Ge layer. Further metallic via structures 1011₂ in additional insulating layers 1012₂ may be formed terminating the metal structure with an electrode 1016 that is provided on the surface of insulator 1012₂. The cross-sectional dimensions of the nano-scale metallic vias (i.e. width and/or diameter) may be selected between 400 and 20 nm, preferably between 200 and 40 nm.

In an embodiment, metals for the metal vias include Al, Nb, NbN, TiN, NbTiN. These metals will become superconducting below a certain critical temperature. Thus providing very low loss electrodes. In a further embodiment, platinum may be used as a metal for the vertical vias thereby forming Pt—SiGe or Pt—Ge contact. An annealing step may be used to form an alloy at the interface of this contacts in to form a platinum silicide compound such as platinum silicide PtSi or platinum germanosilicide PtSiGe or a platinum germanide compound such as platinum germanide PtGe; These platinum silicide and germanide alloys will become superconducting below a critical temperature thus providing very low loss superconducting ohmic contacts with the quantum well.

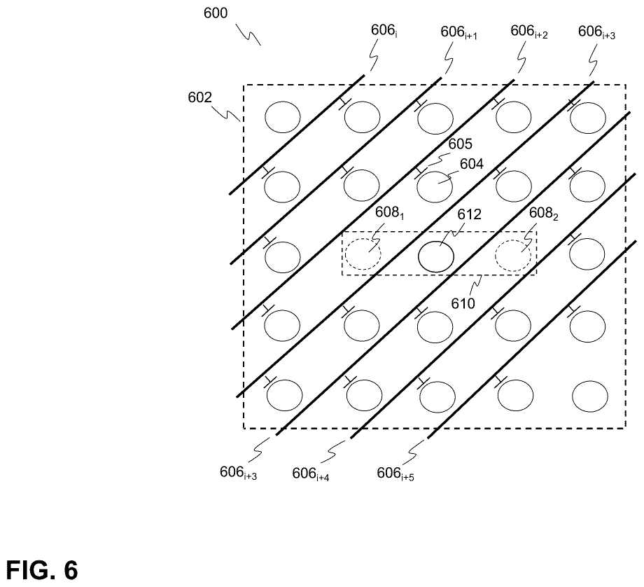

The integrated semiconductor structure of FIG. 5 will subsequently be processed to form both an integrated SET transistor and a gate electrode structure as schematically illustrated in FIG. 6. This figure depicts a schematic of an integrated quantum dot structure including an array of quantum dot regions wherein quantum dot regions in a readout region 610 are configured as a SET transistor. The SET transistor may include a source region 608₁ and drain region 608₂ and an island 612 connected via tunnel barriers to the island. Further, quantum dot regions located around the SET transistor may include a gate structure, e.g. a plurality of electrodes arranged in a predetermined direction over the structure for inducing quantum wells in the quantum dot regions. A gate electrode may include a plurality of plunger gates, wherein a plunger gate 605 may be used to form a quantum well in the quantum dot region.

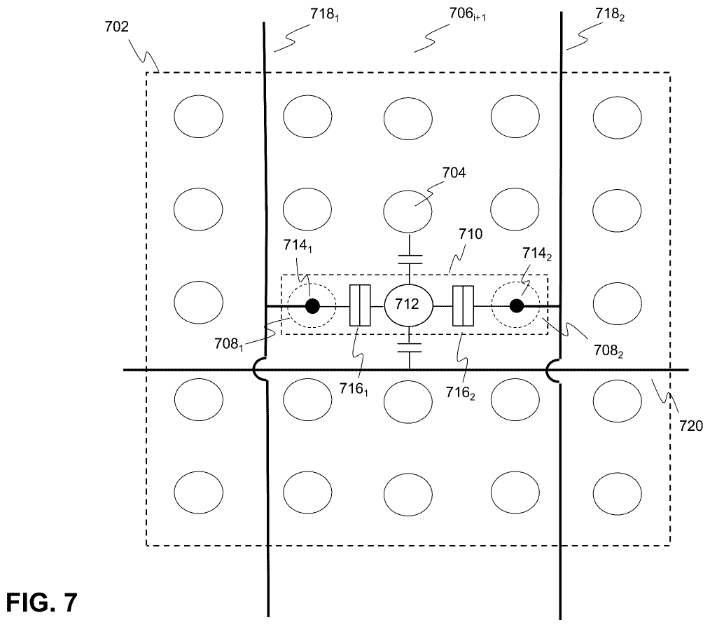

FIG. 7 depicts a schematic of a quantum dot array comprising an integrated SET readout structure according to an embodiment of the invention. In particular, FIG. 7 represents a schematic top view of part of semiconductor substrate 702 comprising regions 704 in which a quantum dot may be formed. The quantum states of a quantum dot, e.g. the spin state of a single charge carrier, e.g. an electron or hole, in the quantum dot, may be operated as a qubit.

Different types of quantum dots may be used, e.g. quantum dots formed in a stack of semiconductor layers in which a two-dimensional electron gas (2DEG) or a two-dimensional hole gas (2DHG) is formed. Such stack may be referred to as a quantum well stack, which are well known in the field. Quantum well stacks may be based on group IV type, group Ill-V and group II-VI type thin-film semiconductors layers. Other types of quantum dots which may be used with the embodiments in this disclosure include nano-wire type quantum dots, MOS-type quantum dots or self-assembled quantum dots.

Gate electrodes may be arranged over the substrate wherein each electrode may be connected to a plurality of plunger gates. Further, one or more dielectric layers may be used to separate the gate electrodes from the semiconductor layers in which the quantum dots are formed. A gate electrode may be used to control the potential of a row of quantum dots. In particular, such gate electrode may be used to control the number of charge carriers in the quantum dot. Examples of electrode structures for controlling the quantum dot and the SET transistor will be described hereunder in more detail.

A readout area 710 located inside (i.e. within) the quantum dot array may comprise a readout structure for quantum dots arranges around the readout structure. Thus, the SET transistor is located in the central part of the quantum dot array, away from the quantum dots that form the peripheral part of the quantum dot array. Quantum dot array 702 depicted in the figure may be part of an extended, densely packet quantum dot array of hundreds or even thousands quantum dot regions. For example, the quantum dot array including the SET readout structure may form a unit cell of a large area quantum dot array with a plurality of SET readout structures arranged within the quantum dot area.

In some of the embodiments, the readout area may include space for forming a single electron tunneling (SET) transistor within quantum dot array. The readout areas may include source and drain regions 708_{1,2} and a small conductive island 712 formed between the source and drain regions. The source and drain regions may be connected to source and drain electrode that are provided over the 2D quantum dot array. One or more dielectric layers may be used to separate the source and drain electrode from the gate electrode.

Metallic nano-scale vias 714_{1,2} in the dielectric layer may be used to electrically connect the source and drain regions of the SET in the semiconductor layer with the source and drain electrodes. The SET island may be connected to the source and drain regions via tunnel barriers 716_{1,2}. Further, a SET transistor gate line 720 may be connected to a plunger gate that is capacitively coupled to the island of the SET transistor. The SET gate electrode may be used to tune the SET transistor so that it can be used as a highly sensitive charge sensor for sensing charge transitions in quantum dots, e.g. quantum dot 704, that is capacitively coupled to the metallic island of the SET transistor.

In some embodiments, the barriers regions between the quantum dots in FIG. 7 may be locally controlled using barrier electrodes. Quantum dots may be configured as qubits and by locally controlling a barrier region between two qubits, the coupling between the qubits can be controlled. The state of the quantum dots before and after interaction can be measured using the SET transistor as a highly sensitive charge sensor which is capacitively coupled to the quantum dots.

Thus, in contrast to prior art quantum dot readout structures, a SET transistor may be formed in a readout area within the array of quantum dots, wherein the source and drain electrodes of the SET transistor are formed in a different layer than the source and drain regions of the SET transistor and nanoscale metallic vias may galvanically connect the source and drain of the SET transistor with the source and drain electrodes. The SET readout structure is easily scalable by integrating a plurality of such SET readout structures regularly distributed over a large area quantum dot structure.

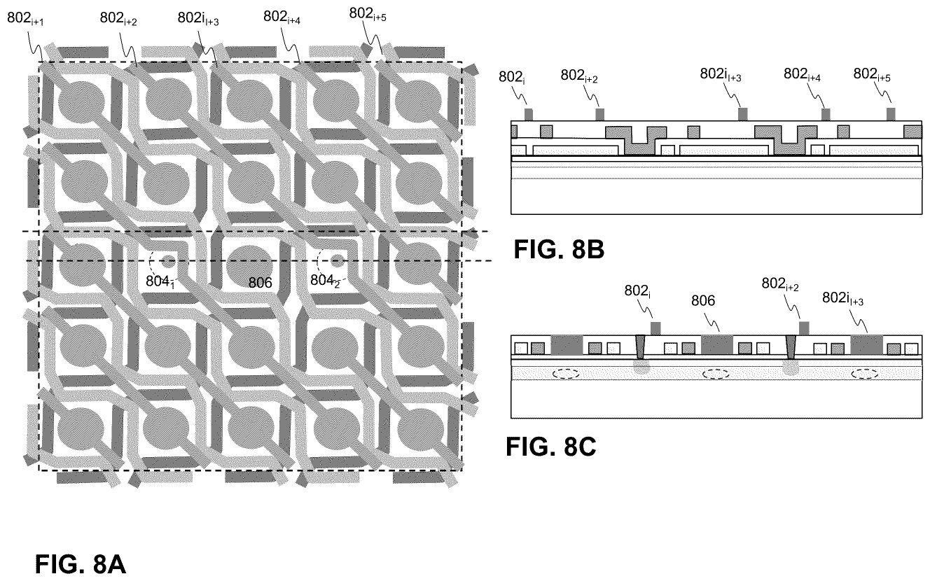

FIG. 8A-8C depict a top view and two cross sections of the semiconductor structure after fourth fabrication steps, which include the formation of a (plunger) gate electrode structures 802ₗ, 802ₗ₊₁, 802ₗ₊₂, 802ₗ₊₃, 802ₗ₊₄, 802ₗ₊₅, on top of the semiconductor structure as shown in FIG. 6A-6C. Hence, each gate electrode defines a row (in this case a diagonal row) of plunger gates for the quantum dot areas, except for the quantum dot areas 804₁, 804₂,806 that are located within the readout area for the SET transistor. As shown in FIG. 8A, when forming the electrode structure, a separate plunger gate 806 for the SET transistor may be formed. Further, no plunger gates are formed at the dot regions 804₁, 804₂ for allowing contact to the vias in a further process step. The formation of this structure may be realized based on lithography steps to form openings for the plunger gates and deposition steps for depositing metallic gate electrodes. These gate electrode structures may include plunger gates arranged in the center of the quantum dot regions so that when a voltage is applied to these gates a quantum well is formed in the one or more semiconductor layers.

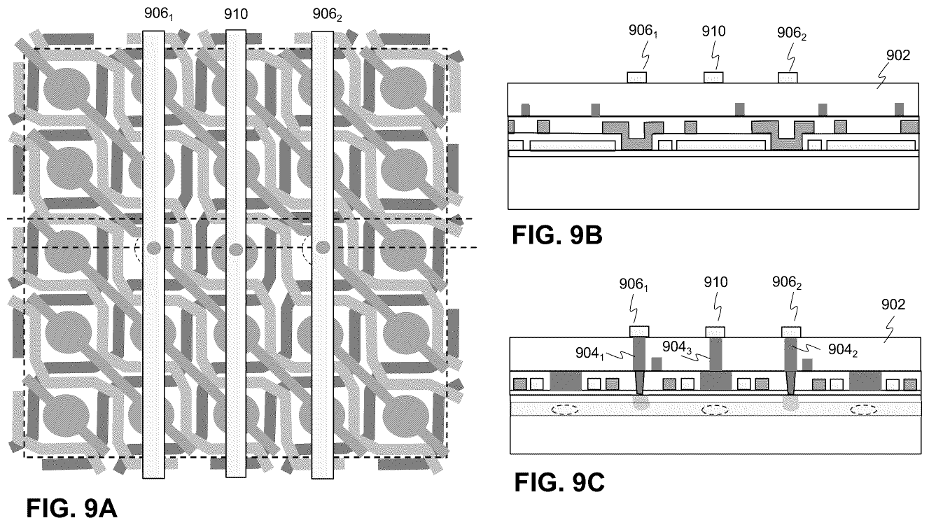

FIG. 9A-9C depict a top view and two cross sections of the semiconductor structure after fifth fabrication steps, which includes the formation of a fourth insulating layer 902 over the semiconductor structure of FIG. 8A-8C and the formation of metallic vias 904₁, 904₂, 904₃ in the fourth insulating layer to provide a galvanic connection between the semiconductor layer and source and drain electrodes 906₁, 906₂ and a connection between the plunger gate of the SET transistor and the SET gate electrode 910, which are provided on the fourth insulating layer. Thereafter, further insulating layers and/or passivation layers may be provided over the semiconductor structure.

Hence, the formation of quantum dots structures comprising a barrier electrode structure and, in some embodiments, an integrated SET readout allows dense integration of large area quantum dot structures. The quantum dot structures include addressable barrier regions allowing quantum dots to be configured as qubits and allowing qubits to interact with each other.

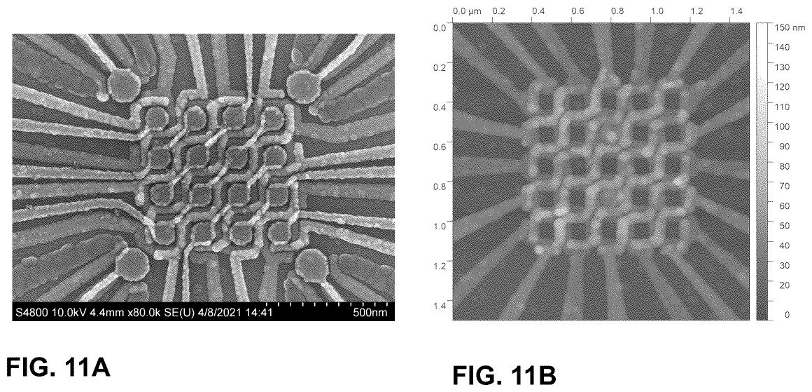

FIGS. 11A and 11B depicts pictures of 2D quantum dot arrays that are realized based (part of) the fabrication steps as described with reference to FIG. 4-9. FIG. 12A shows an example of a 4×4 quantum dot array comprising an addressable double barrier gate structure, but does not include array does not include a SET structure. FIG. 12B depicts a picture of a 5×5 quantum dot array including comprising an addressable double barrier gate structure and integrated SET structure as described with reference to the embodiments in this application.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A quantum dot structure comprising:
one or more semiconductor layers arranged on a substrate;
a plurality of quantum dot regions, the plurality of quantum dot regions being formed in the one or more semiconductor layers, the quantum dot regions being separated by barrier regions; and
first barrier electrodes arranged in one direction over the quantum dot regions and a second barrier electrodes arranged in a second direction over the quantum dot regions, wherein the first barrier electrodes and second barrier electrodes cross each other at the barrier regions so that each barrier region is coupled to one of the first barrier electrodes and one of the second barrier electrodes.

2. The quantum dot structure according to claim 1 wherein one or more first barrier electrodes and one or more second barrier electrodes form a multi-barrier electrode structure arranged over one of the barrier regions.

3. The quantum dot structure according to claim 1 wherein the one or more first barrier electrodes are arranged over the substrate in a first diagonal direction and the one or more second barrier electrodes in a second diagonal direction.

4. The quantum dot structure according to claim 3 wherein the one or more first barrier electrodes and the one or more second barrier electrodes are arranged over the barrier regions.

5. The quantum dot structure according to claim 1 wherein gate electrodes are arranged over the substrate, each gate electrode comprising a plurality of plunger gates arranged over a plurality of quantum dot regions.

6. The quantum dot structure according to claim 1 wherein one or more insulating layers electrically insulate the first barrier electrodes and the second barrier electrodes from the one or more semiconducting layers.

7. The quantum dot structure according to claim 6 further including one or more single electron tunneling (SET) transistors formed in the one or more semiconductor layers, each of the one or more SET transistors comprising a source and a drain connected by tunneling junctions to a conductive island.

8. The quantum dot structure according to claim 7 further comprising
a source electrode and a drain electrode arranged over the one or more insulating layers; and,
a first and second nano-scale metallic via through the one or more insulating layers for connecting the source and the drain of one of the one or more SET transistors to the source and drain electrodes arranged over the one or more insulating layers respectively.

9. The quantum dot structure according to claim 8 wherein cross-sectional dimensions of the first and second nano-scale metallic vias are selected between 500 and 20 nm.

10. The quantum dot structure according to claim 1 wherein dimensions of the quantum dot regions are selected between 200 and 20 nm.

11. The quantum dot structure according to claim 1 wherein the one or more semiconductor layers include a semiconductor heterostructure, a MOS structure, a semiconductor-on-insulator structure, or geometries comprising finFET, nanowires, hut wire, or self-assembled structures.

12. The quantum dot structure according to claim 1 wherein the plurality of quantum dot regions forms a 2D array of quantum dot regions or a 3D array of quantum dot regions.

13. (canceled)

14. A quantum dot processor comprising:
a quantum dot structure comprising:
one or more semiconductor layers arranged on a substrate;
a plurality of quantum dot regions, the plurality of quantum dot regions being formed in the one or more semiconductor layers; the quantum dot regions being separated by barrier regions;
first barrier electrodes arranged in one direction over the quantum dot structure and second barrier electrodes arranged in a second direction over the quantum dot structure, wherein the first barrier electrodes crosses the second barrier electrodes at the barrier regions so that each barrier region is coupled to one of the first barrier electrodes and one of the second barrier electrodes; and,
a controller configured to locally change a coupling between two neighboring quantum dots of the plurality of quantum dot regions based on the first barrier electrodes and the second barrier electrodes.

15. The quantum dot processor according to claim 14, wherein the controller is configured to:
select one or more first barrier electrodes from the first barrier electrodes and one or more second barrier electrodes from the second barrier electrodes, the one or more selected first and second barrier electrodes crossing each other at a barrier region between the two neighboring quantum dots;
apply a signal to each of the one or more selected first barrier electrodes and a signal to each of the one or more selected second barrier electrodes.

16. The quantum dot processor according to claim 15, wherein the controller is configured to apply simultaneously the signal to each of the one or more selected first barrier electrodes and the signal to each of the one or more selected second barrier electrodes.

17. The quantum dot structure according to claim 8 further comprising:
a third nano-scale metallic via through the one or more insulating layers for connecting a plunger electrode that is capacitively connected to the conductive island to a gate electrode arranged over the one or more insulating layers.

18. The quantum dot structure according to claim 8, wherein one end of the first nano-scale metallic via and one end of the second nano-scale metallic via form ohmic contacts with the one or more semiconductor layers.

19. The quantum dot structure according to claim 18, wherein the ohmic contacts comprise nano-scale ohmic contacts.

20. The quantum dot structure according to claim 5, wherein the first barrier electrodes, the second barrier electrodes or the gate electrodes are made of metal that becomes superconductive below a critical temperature.
